(19) United States
(12) Patent Application Publication
(10) Pub. No.: US 2023/0025912 A1
(43) Pub. Date: Jan. 26, 2023

(54) DISPLAY DEVICE

(71) Applicant: Samsung Display Co., LTD., Yongin-si (KR)

(72) Inventors: Joon Woo BAE, Hwaseong-si (KR); Keun Woo Kim, Seongnam-si (KR); Jae Hwan CHU, Hwaseong-si (KR); Sang Gun CHOI, Suwon-si (KR)

(21) Appl. No.: 17/870,796

(22) Filed: Jul. 21, 2022

(30) Foreign Application Priority Data
Jul. 22, 2021 (KR) 10-2021 -0096368

(51) Int. Cl. H01L 27/32

(52) U.S. Cl. CPC H01L 27/3262; H01L 27/3276

(57) ABSTRACT

A display device including: a display area including a plurality of pixels; and a peripheral area disposed around the display area to include a driving signal transmission line, each of the pixels may include a transistor, a driving voltage line connected to the transistor and the driving signal transmission line, and a light emitting unit connected to the transistor, the pixels may include a first pixel and a second pixel spaced apart from the driving signal transmission line to have different distances from each other, and a concentration of impurities doped in a semiconductor layer of the transistor of the first pixel may be different from a concentration of impurities doped in a semiconductor layer of the transistor of the second pixel.

### CROSS REFERENCE TO RELATED APPLICATION

This application claims priority from and benefit of Korean Patent Application No. 10-2021-0096368, filed on Jul. 22, 2021, which is hereby incorporated by reference for all purposes as if fully set forth herein.

### BACKGROUND

### Field

Embodiments relate generally to a display device.

### Discussion of the Background

A flat panel display may include a liquid crystal display (LCD), a plasma display panel (PDP), an organic light emitting diode device (OLED device), a field effect display (FED), an electrophoretic display device, and the like.

The display device includes a display area including a plurality of pixels including a light emitting unit and a plurality of signal lines connected to the light emitting unit, and a peripheral area disposed around the display area and including a driving signal transfer unit for transferring driving signals to the signal lines.

When a driving signal is transferred from the driving signal transfer unit disposed in the peripheral area, magnitudes of the driving signals transferred to a pixel disposed close to the driving signal transfer unit and a pixel disposed far from the driving signal transfer unit may be different by a voltage drop of a driving signal line connected to the driving signal transfer unit. Accordingly, brightness of the light emitting unit may not be uniform.

The above information disclosed in this Background section is only for enhancement of understanding of the background of the described technology, and therefore, it may contain information that does not form the prior art that is already known in this country to a person of ordinary skill in the art.

### SUMMARY

Embodiments provide a display device in which brightness of a light emitting unit is uniform regardless of a position of a pixel by compensating for a change in a magnitude of a driving voltage according to resistance of a driving voltage line depending on the position of the pixel.

Additional features of the inventive concepts will be set forth in the description which follows, and in part will be apparent from the description, or may be learned by practice of the inventive concepts.

An embodiment provides a display device including: a display area including a plurality of pixels; and a peripheral area disposed around the display area to include a driving signal transmission line. Each of the pixels may include a transistor, a driving voltage line connected to the transistor and the driving signal transmission line, and a light emitting unit connected to the transistor. The pixels may include a first pixel and a second pixel spaced apart from the driving signal transmission line to have different distances from each other. A concentration of impurities doped in a semiconductor layer of the transistor of the first pixel may be different from a concentration of impurities doped in a semiconductor layer of the transistor of the second pixel.

A distance between the driving signal transmission line and the second pixel may be greater than a distance between the driving signal transmission line and the first pixel, and the concentration of the impurities doped in the semiconductor layer of the transistor of the second pixel may be greater than the concentration of the impurities doped in the semiconductor layer of the transistor of the first pixel.

The semiconductor layer of the transistor may include a channel overlapping a gate electrode, and first and second regions disposed on opposite sides of the channel, and the first region of the transistor may be connected to the driving voltage line, and the transistor may receive a driving voltage from the driving voltage line.

The first region and the second region of the transistor may be doped with the impurities.

The display device may further include a resistance pattern connected to the driving voltage line of the first pixel.

The display area may include a first area disposed close to the driving signal transmission line, a second area disposed farther from the driving signal transmission line than the first region, and a third area disposed between the first area and the second area, the first pixel may be disposed in the first area. The second pixel may be disposed in the second area, and the concentration of the impurities doped in the semiconductor layer of the transistor of the second pixel may be greater than the concentration of the impurities doped in the semiconductor layer of the transistor of the first pixel.

The pixels may further include a third pixel disposed in the third area, and a concentration of impurities doped in the semiconductor layer of the transistor of the third pixel may be greater than the concentration of the impurities doped in the semiconductor layer of the transistor of the first pixel, and may be smaller than the concentration of the impurities doped in the semiconductor layer of the transistor of the second pixel.

The display device may further include a first resistor connected to the driving voltage line of the first pixel and a second resistor connected to the driving voltage line of the third pixel, and a resistance of the first resistor may be different from a resistance of the second resistor.

The resistance of the first resistor may be greater than the resistance of the second resistor.

Another embodiment provides a display device including: a display area including a plurality of pixels; and a peripheral area disposed around the display area to include a driving signal transmission line. The pixels may include a first pixel and a second pixel spaced apart from the driving signal transmission line to have different distances from each other. A distance between the driving signal transmission line and the second pixel may be greater than a distance between the driving signal transmission line and the first pixel. The first pixel may include a transistor, a driving voltage line connected to the transistor and the driving signal transmission line, and a first resistor connected to the driving voltage line. The second pixel may include the transistor and the driving voltage line.

The driving voltage line of the second pixel may not be connected to the first resistor.

The display area may include a first area disposed close to the driving signal transmission line, a second area disposed farther from the driving signal transmission line than the first region, and a third area disposed between the first area and the second area, the first pixel may be disposed in the first area. The second pixel may be disposed in the second area. The driving voltage line of the third pixel disposed in the third area may be connected to a second resistor. A magnitude of the first resistor may be different from a magnitude of the second resistor.

The first resistance pattern may be disposed under the driving voltage line with an insulating layer therebetween, and the driving voltage line may be connected to the first resistance pattern through a contact hole of the insulating layer.

The pixels may include a semiconductor layer, a gate conductor overlapping the semiconductor layer, and a data conductor connected to the semiconductor layer, and the first resistance pattern may be formed at a same layer as any one of the semiconductor layer, the gate conductor, and the data conductor.

According to the embodiments, brightness of a light emitting unit may be uniform regardless of a position of a pixel of a display device by compensating for a change in a magnitude of a driving voltage according to resistance of a driving voltage line depending on the position of the pixel.

It is to be understood that both the foregoing general description and the following detailed description are illustrative and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate illustrative embodiments of the invention, and together with the description serve to explain the inventive concepts.

FIG. 1 illustrates a top plan view of a display device according to an embodiment.

FIG. 2 illustrates a circuit diagram of a display device according to an embodiment.

FIG. 3 illustrates a top plan view of a display device according to an embodiment.

FIG. 4 illustrates a cross-sectional view taken along a line IV-IV of FIG. 3.

FIG. 5 illustrates a cross-sectional view taken along a line V-V of FIG. 3.

FIGS. 6, 7, 8, 9, 10, 11, and 12 illustrate top plan views sequentially showing a display device depending on a manufacturing order thereof according to an embodiment.

FIGS. 13, 14, and 15 each illustrate a cross-sectional view of a display device according to an embodiment.

FIG. 16 illustrates a schematic view showing a manufacturing method of a display device according to an embodiment.

FIG. 17 and FIG. 18 each illustrate a top plan view of one pixel of a display device according to another embodiment.

FIGS. 19, 20, and 21 each illustrate a cross-sectional view of a portion of one pixel of a display device according to another embodiment.

### DETAILED DESCRIPTION

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods employing one or more of the inventive concepts disclosed herein. It is apparent, however, that various embodiments may be practiced without these specific details or with one or more equivalent arrangements. In other instances, well-known structures and devices are shown in block diagram form in order to avoid unnecessarily obscuring various embodiments. Further, various embodiments may be different, but do not have to be exclusive. For example, specific shapes, configurations, and characteristics of an embodiment may be used or implemented in another embodiment without departing from the inventive concepts.

Unless otherwise specified, the illustrated embodiments are to be understood as providing illustrative features of varying detail of some ways in which the inventive concepts may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the D1-axis, the D2-axis, and the D3-axis are not limited to three axes of a rectangular coordinate system, such as the x, y, and z-axes, and may be interpreted in a broader sense. For example, the D1-axis, the D2-axis, and the D3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of idealized embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and should not be interpreted in an idealized or overly formal sense, unless expressly so defined herein.

Hereinafter, various embodiments and variations will be described in detail with reference to the drawings.

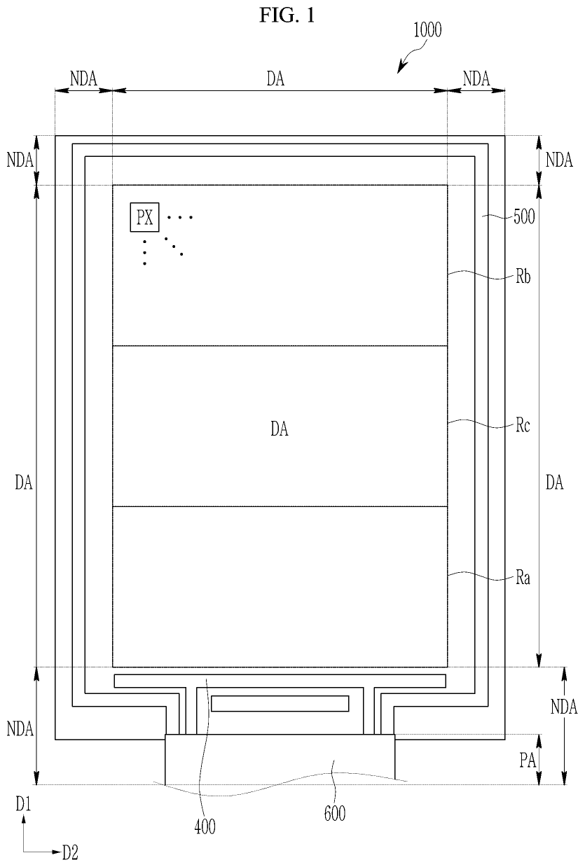

Hereinafter, a display device according to an embodiment will be described with reference to FIG. 1. FIG. 1 illustrates a top plan view of a display device according to an embodiment.

Referring to FIG. 1, a display device 1000 according to the present embodiment includes a display area DA including a plurality of pixels and displaying an image and a non-display area NDA disposed outside the display area DA.

The non-display area NDA includes a driving area PA in which a driver 600 for transferring a signal to the display area DA is disposed. For example, an external device, such as a driving chip, may be mounted in the driving area PA, or may be connected to the external device through a flexible circuit board.

A first driving signal transmission line 400 and a second driving signal transmission line 500 each transmitting a driving voltage are disposed in the non-display area NDA. Pad electrodes electrically connected to an external device and a plurality of connection lines connected thereto may be disposed in the non-display area NDA. The connection lines may receive a data signal, a scan signal, an emission signal, a power voltage, a touch sensing signal, or the like from the driving area PA to transmit it to the display area DA. The connection lines may be a fan out portion.

According to the illustrated embodiment, the first driving signal transmission line 400 has a shape extending along a first direction D1, and the second driving signal transmission line 500 has a shape that starts from the driver 600 and surrounds the display area DA along the non-display area NDA, but this is an example, and arrangement of the first driving signal transmission line 400 and the second driving signal transmission line 500 is not limited thereto.

For example, the first driving signal transmission line 400 may transmit a driving voltage, and the second driving signal transmission line 500 may transmit a common voltage.

Although not illustrated, the driving area PA may be disposed at opposite sides along a second direction D2.

The display area DA may include a first area Ra disposed close to the first driving signal transmission line 400, a second area Rb disposed far from the first driving signal transmission line 400, and a third area Rc disposed between the first area Ra and the second area Rb.

According to the illustrated embodiment, the first driving signal transmission line 400, the first area Ra, the third area Rc, and the second area Rb may be sequentially disposed along the first direction DR1.

However, according to another embodiment, the first driving signal transmission line 400 may be disposed at opposite sides of the display area DA along the first direction DR1. In this case, the first area Ra may be disposed at opposite edges of the display area DA along the first direction DR1, the second area Rb may be disposed at a center of the display area DA, and the third area Rc may be disposed between the opposite edges and the center of the display area DA.

When a first driving signal is transmitted to the display area DA through the first driving signal transmission line 400, a magnitude of the first driving signal may be reduced toward the first area Ra, the third area Rc, and the second area Rb by resistance of a driving signal line of the display area DA connected to the first driving signal transmission line 400. However, in accordance with the display device according to the embodiment, the magnitude of the driving signal transmitted to the display area DA may be substantially constant regardless of the first area Ra, the third area Rc, and the second area Rb.

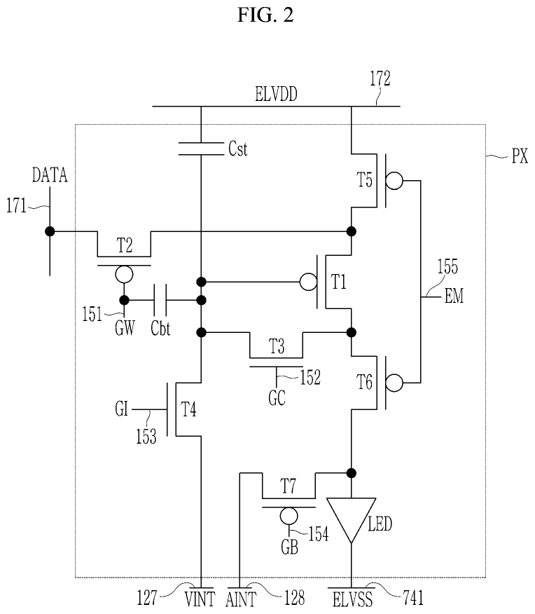

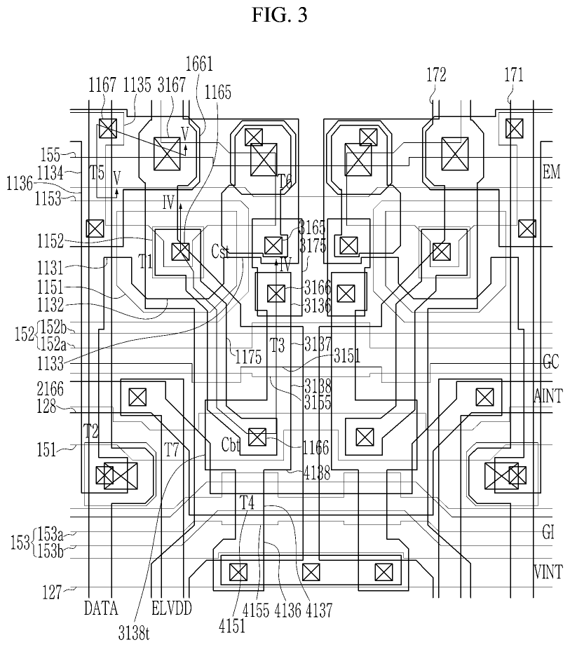

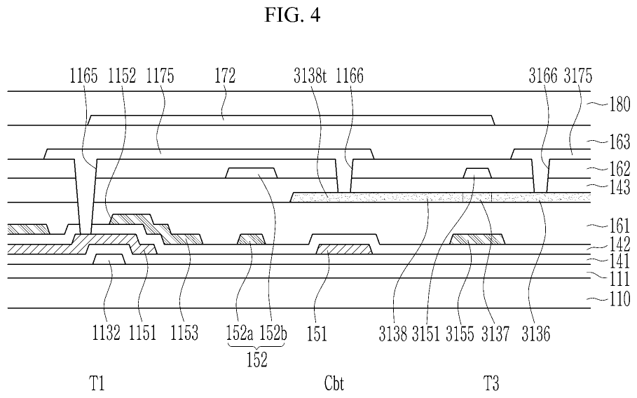

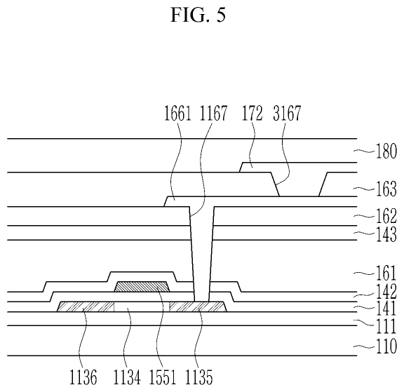

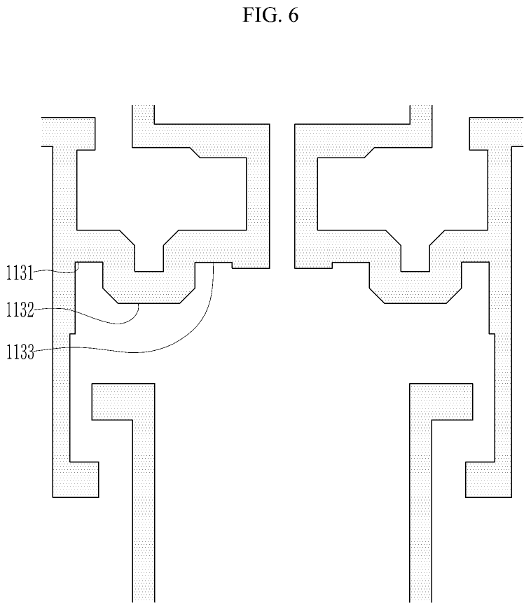

Next, one pixel PX of the display area DA of the display device according to an embodiment will be described in more detail with reference to FIG. 2 to FIG. 12. FIG. 2 illustrates a circuit diagram of a display device according to an embodiment; FIG. 3 illustrates a top plan view of a display device according to an embodiment; FIG. 4 illustrates a cross-sectional view taken along a line IV-IV of FIG. 3; and FIG. 5 illustrates a cross-sectional view taken along a line V-V of FIG. 3. FIG. 6 to FIG. 12 illustrate top plan views sequentially showing a display device depending on a manufacturing order thereof according to an embodiment.

First, a circuit diagram of one pixel PX in the display area DA of the display device according to an embodiment will be described with reference to FIG. 2.

As illustrated in FIG. 2, one pixel PX in the display area DA of the display device according to the present embodiment may include a plurality of transistors T1, T2, T3, T4, T5, T6, and T7, a storage capacitor Cst, a boost capacitor Cbt, and a light emitting diode LED connected to various wires 127, 128, 151, 152, 153, 154, 155, 171, 172, and 741.

The wires 127, 128, 151, 152, 153, 154, 155, 171, 172, and 741 are connected to one pixel PX. The wires include a first initialization voltage line 127, a second initialization voltage line 128, a first scan line 151, a second scan line 152, an initialization control line 153, a bypass control line 154, a bypass control line 155, a data line 171, a driving voltage line 172, and a common voltage line 741.

The first scan line 151 is connected to a gate driver (not illustrated) to transmit a first scan signal GW to the second transistor T2. A voltage having a polarity that is opposite to that of the voltage applied to the first scan line 151 may be applied to the second scan line 152 at a same timing as a signal of the first scan line 151. For example, when a negative voltage is applied to the first scan line 151, a positive voltage may be applied to the second scan line 152. The second scan line 152 transmits a second scan signal GC to the third transistor T3.

The initialization control line 153 transmits an initialization control signal GI to the fourth transistor T4. The bypass control line 154 transfers a bypass signal GB to the seventh transistor T7. The bypass control line 154 may be formed by a previous-stage first scan line 151. The emission control line 155 transmits an emission control signal EM to the fifth transistor T5 and the sixth transistor T6.

The data line 171 is a wire for transmitting a data voltage DATA generated by a data driver (not illustrated), and luminance of the organic light emitting diode LED that emits light is changed depending on the data voltage DATA applied to the pixel PX.

The driving voltage line 172 applies a driving voltage ELVDD. The first initialization voltage line 127 transfers a first initialization voltage VINT, and the second initialization voltage line 128 transfers the second initialization voltage AINT. The common voltage line 741 applies a common voltage ELVSS to a cathode of the light emitting diode LED. In the present embodiment, voltages applied to the driving voltage line 172, the first and second initialization voltage lines 127 and 128, and the common voltage line 741 may all be constant voltages.

The transistors may include a driving transistor T1, a second transistor T2, a third transistor T3, a fourth transistor T4, a fifth transistor T5, a sixth transistor T6, and a seventh transistor T7. The transistors may include an oxide transistor including an oxide semiconductor and a polycrystalline transistor including a polycrystalline semiconductor. For example, the third transistor T3 and the fourth transistor T4 may be formed as oxide transistors, and the driving transistor T1, the second transistor T2, the fifth transistor T5, the sixth transistor T6, and the seventh transistor T7 may be formed as polycrystalline transistors. However, the inventive concepts are not limited thereto, and the transistors may all be made as polycrystalline transistors.

Previously, it has been described that one pixel PX includes seven transistors T1 to T7, one storage capacitor Cst, and one boost capacitor Cbt, but the inventive concepts are not limited thereto, and a number of transistors, a number of capacitors, and their connection relationship may be variously changed.

Next, an interlayer structure of one pixel PX of the display area DA of the display device according to an embodiment will be described in more detail with reference to FIG. 3 to FIG. 12.

Referring to FIG. 3 to FIG. 6, a buffer layer 111 may be disposed on a substrate 110, and a polycrystalline semiconductor layer including a channel 1132, a first area 1131, and a second area 1133 of the driving transistor T1, and a channel 1134, a first area 1135, and a second area 1136 of the fifth transistor T5 may be disposed on the buffer layer 111. FIG. 6 illustrates the polycrystalline semiconductor layer. The polycrystalline semiconductor layer may further include a channel, a first area, and a second area of each of the second transistor T2, the sixth transistor T6, and the seventh transistor T7 in addition to the driving transistor T1 and the fifth transistor T5.

The channel 1132 of the driving transistor T1 may have a bent shape in a plan view. However, the shape of the channel 1132 of the driving transistor T1 is not limited thereto, and may be variously changed. For example, the channel 1132 of the driving transistor T1 may be bent in a different shape, or may be formed in a bar-like shape. The first area 1131 and the second area 1133 of the driving transistor T1 may be disposed at opposite sides of the channel 1132 of the driving transistor T1. The first area 1131 of the driving transistor T1 extends upward and downward in a plan view, a portion extending downward may be connected to the second area of the second transistor T2, and a portion extending upward may be connected to the second area 1136 of the fifth transistor T5. The second area 1133 of the driving transistor T1 may extend upward in a plan view to be connected to the first area of the sixth transistor T6.

The first area 1135 and the second area 1136 of the fifth transistor T5 may be disposed at opposite sides of the channel 1134 of the fifth transistor T5. The second area 1136 of the fifth transistor T5 may be connected to the first area 1131 of the driving transistor T1.

A first gate insulating layer 141 may be disposed on the polycrystalline semiconductor layer including the channel 1132, the first area 1131, and the second area 1133 of the driving transistor T1, and the channel 1134, the first area 1135, and the second area 1136 of the fifth transistor T5.

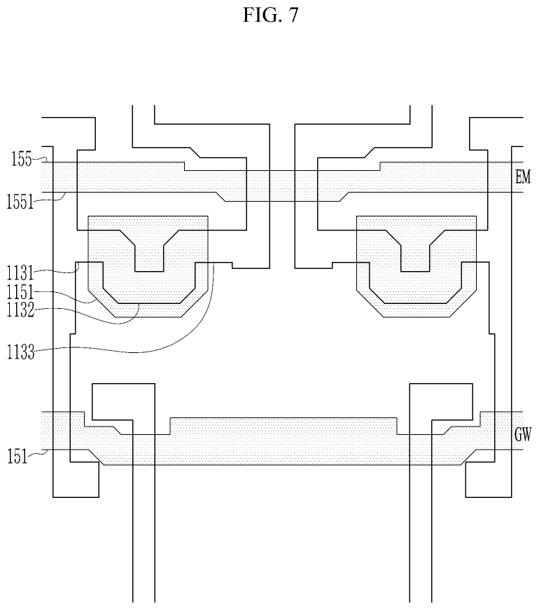

A first gate conductor including a gate electrode 1151, a first scan line 151, and an emission control line 155 of the driving transistor T1 may be disposed on the first gate insulating layer 141. FIG. 7 illustrates the polycrystalline semiconductor layer and the first gate conductor together. The gate conductor may further include a gate electrode of each of the second transistor T2, the fifth transistor T5, the transistor T6, and the seventh transistor T7 as well as the driving transistor T1.

The gate electrode 1151 of the driving transistor T1 may overlap the channel 1132 of the driving transistor T1. The channel 1132 of the driving transistor T1 may overlap the electrode channel 1151 of the driving transistor T1.

The first scan line 151 and the emission control line 155 may extend substantially in a horizontal direction. The first scan line 151 may be integrally formed with the gate electrode of the second transistor T2. The bypass control line connected to the seventh transistor T7 may be formed as the first scan line 151 of a previous stage. The gate electrode 1551 of the fifth transistor T5 and the gate electrode of the sixth transistor T6 may be integrally formed with the emission control line 155.

The gate electrode 1551 of the fifth transistor T5 may overlap the channel 1134 of the fifth transistor T5. The channel 1134 of the fifth transistor T5 may overlap the electrode channel 1551 of the fifth transistor T5.

A doping process may be performed after the first gate conductor including the gate electrode 1151, the first scan line 151, and the emission control line 155 illustrated in FIG. 7 is formed. The polycrystalline semiconductor layer that is covered by the first conductive layer may be doped, and a portion of the polycrystalline semiconductor layer that is not covered by the first conductive layer may be doped to have a same characteristic as that of a conductor. In this case, the doping process may be performed with a P-type dopant, and the driving transistor T1, the second transistor T2, the third transistor T3, the fifth transistor T5, the sixth transistor T6, and the seventh transistor T7 may have a P-type transistor characteristic.

The first area 1131 and the second area 1133 disposed at opposite sides of the channel 1132 of the driving transistor T1 and the first area 1135 and the second area 1136 disposed at opposite sides of the channel 1134 of the fifth transistor T5 may be doped with impurities to have a same characteristic as a conductor by performing a doping process after forming the first gate conductor, and as an amount of the doped impurities increases, conductivity of the first area 1135 and the second area 1136 disposed at opposite sides of the channel 1134 of the fifth transistor T5 may be increased.

A second gate insulating layer 142 may be disposed on the first gate insulating layer 141 and the first gate conductor including the gate electrode 1151 and the first scan line 151.

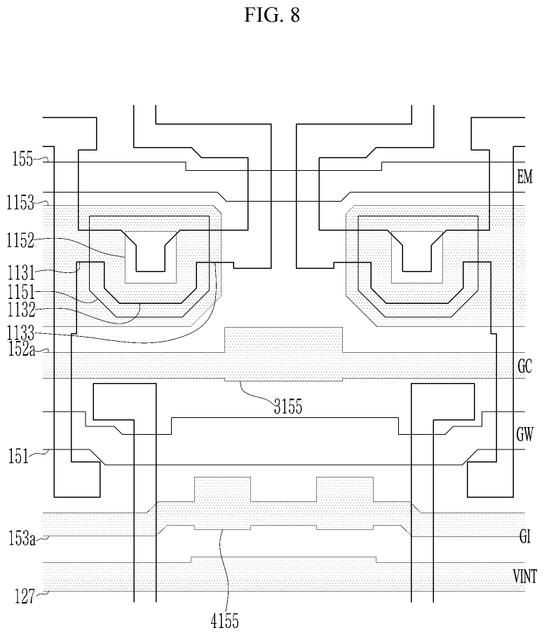

A second gate conductor including a first storage electrode 1153 of the storage capacitor Cst, a lower gate electrode 3155 of the third transistor T3, and a lower gate electrode 4155 of the fourth transistor T4 may be disposed on the second gate insulating layer 142. FIG. 8 illustrates a polycrystalline semiconductor, a first gate conductor, and a second gate conductor together.

The first storage electrode 1153 overlaps the gate electrode 1151 of the driving transistor T1 to constitute the storage capacitor Cst. An opening 1152 is formed in the first storage electrode 1153 of the storage capacitor Cst. The opening 1152 of the first storage electrode 1153 of the storage capacitor Cst may overlap the gate electrode 1151 of the driving transistor T1. The lower gate electrode 3155 of the third transistor T3 may overlap the channel 3137 and an upper gate electrode 3151 of the third transistor T3. The lower gate electrode 4155 of the fourth transistor T4 may overlap the channel 4137 and an upper gate electrode 4151 of the fourth transistor T4.

The second gate conductor may further include a lower second scan line 152a, a lower initialization control line 153a, and a first initialization voltage line 127. The lower second scan line 152a, the lower initialization control line 153a, and the first initialization voltage line 127 may extend substantially in a horizontal direction. The lower second scan line 152a may be integrally formed with the lower gate electrode 3155 of the third transistor T3. The lower initialization control line 153a may be integrally formed with the lower gate electrode 4155 of the fourth transistor T4.

A first interlayer insulating layer 161 may be disposed on the second gate conductor including the first storage electrode 1153 of the storage capacitor Cst, the lower gate electrode 3155 of the third transistor T3, and the lower gate electrode 4155 of the fourth transistor T4.

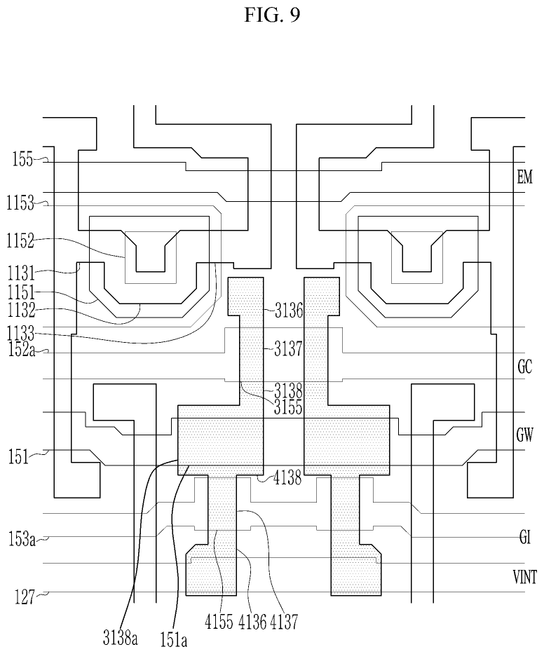

An oxide semiconductor layer including the channel 3137, the first area 3136, and the second area 3138 of the third transistor T3, and the channel 4137, the first area 4136, and the second area 4138 of the fourth transistor T4, may be disposed on the first interlayer insulating layer 161. FIG. 9 illustrates a polycrystalline semiconductor layer, a first gate conductor, a second gate conductor, and an oxide semiconductor layer together.

The channel 3137, the first area 3136, and the second area 3138 of the third transistor T3, and the channel 4137, the first area 4136, and the second area 4138 of the fourth transistor T4, may be connected to each other to be formed integrally. The first area 3136 and the second area 3138 of the third transistor T3 may be disposed at opposite sides of the channel 3137 of the third transistor T3. The first area 4136 and the second area 4138 of the fourth transistor T4 may be disposed at opposite sides of the channel 4137 of the fourth transistor T4. The second area 3138 of the third transistor T3 may be connected to the second area 4138 of the fourth transistor T4. The channel 3137 of the third transistor T3 may overlap the lower gate electrode 3155. The channel 4137 of the fourth transistor T4 may overlap the lower gate electrode layer 4155.

A third gate insulating layer 143 may be disposed on the oxide semiconductor layer including the channel 3137, the first area 3136, and the second area 3138 of the third transistor T3, and the channel 4137, the first area 4136, and the second area 4138 of the fourth transistor T4. The third gate insulating layer 143 may be disposed on entire surfaces of the oxide semiconductor layer and the first interlayer insulating layer 161. Accordingly, the third gate insulating layer 143 may cover upper surfaces and side surfaces of the channel 3137, the first area 3136, and the second area 3138 of third transistor T3, and the channel 4137, the first area 4136, and the second area 4138 of the fourth transistor T4. However, the inventive concepts are not limited thereto, and the third gate insulating layer 143 may not be disposed on entire surfaces of the oxide semiconductor layer and the first interlayer insulating layer 161. For example, the third gate insulating layer 143 may overlap the channel 3137 of the third transistor T3, and may not overlap the first area 3136 and the second area 3138. In addition, the third gate insulating layer 143 may overlap the channel 4137 of the fourth transistor T4, and may not overlap the first area 4136 and the second area 4138.

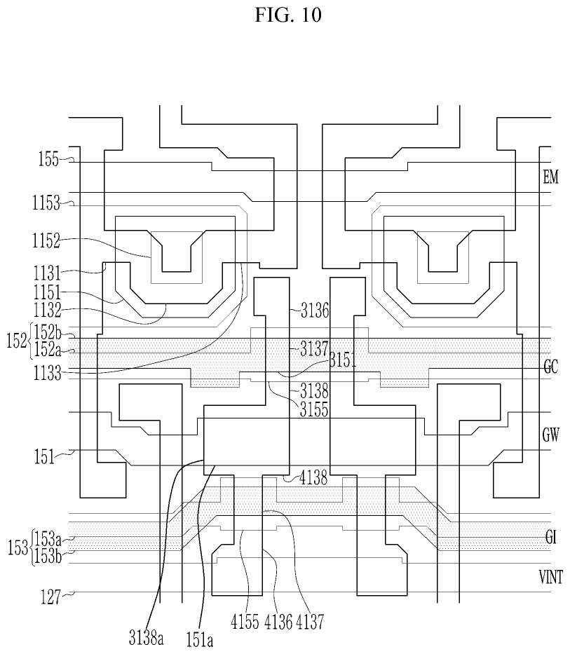

A third gate conductor including the upper gate electrode 3151 of the third transistor T3 and the upper gate electrode 4151 of the fourth transistor T4 may be disposed on the third gate insulating layer 143. FIG. 10 illustrates a polycrystalline semiconductor layer, a first gate conductor, a second gate conductor, an oxide semiconductor layer, and a third gate conductor together.

The upper gate electrode 3151 of the third transistor T3 may overlap the channel 3137 of the third transistor T3. The upper gate electrode 3151 of the third transistor T3 may overlap the lower gate electrode 3155 of the third transistor T3.

The upper gate electrode 4151 of the fourth transistor T4 may overlap the channel 4137 of the fourth transistor T4. The upper gate electrode 4151 of the fourth transistor T4 may overlap the lower gate electrode 4155 of the fourth transistor T4.

The third gate conductor may further include an upper second scan line 152b, an upper initialization control line 153b, and a first connection electrode 2175.

The upper second scan line 152b and the upper initialization control line 153b may extend substantially in the horizontal direction. The upper second scan line 152b may be connected to the upper gate electrode 3151 of the third transistor T3. The upper second scan line 152b may be integrally formed with the upper gate electrode 3151 of the third transistor T3. The upper initialization control line 153b constitutes the initialization control line 153 together with the lower initialization control line 153a. The upper initialization control line 153b may be connected to the upper gate electrode 4151 of the fourth transistor T4. The upper initialization control line 153b may be integrally formed with the upper gate electrode 4151 of the fourth transistor T4.

After the third gate conductor including the upper gate electrode 3151 of the third transistor T3 and the upper gate electrode 4151 of the fourth transistor T4 is formed, a doping process may be performed. A portion of the oxide semiconductor layer covered by the third gate conductor may not be doped, and a portion of the oxide semiconductor layer not covered by the third gate conductor may be doped to have a same characteristic as the conductor. The channel 3137 of the third transistor T3 may be disposed under the upper gate electrode 3151 to overlap the upper gate electrode 3151. The first area 3136 and the second area 3138 of the third transistor T3 may not overlap the upper gate electrode 3151. The channel 4137 of the fourth transistor T4 may be disposed under the upper gate electrode 4151 to overlap the upper gate electrode 4151. The first area 4136 and the second area 4138 of the fourth transistor T4 may not overlap the upper gate electrode 4151. An upper boost electrode 3138t may not overlap the third gate conductor. The doping process of the oxide semiconductor layer may be performed with an N-type dopant, and the third transistor T3 and the fourth transistor T4 including the oxide semiconductor layer may have an N-type transistor characteristic.

A second interlayer insulating layer 162 may be disposed on the third gate conductor including the upper gate electrode 3151 of the third transistor T3 and the upper gate electrode 4151 of the fourth transistor T4. The second interlayer insulating layer 162 may have a single or multi-layered structure. The second interlayer insulating layer 162 may include an inorganic insulating material, such as a silicon nitride (SiNₓ, a silicon oxide (SiOₓ), and a silicon oxynitride (SiOₓN_{y}). The second interlayer insulating layer 162 may include a third opening 1165, a fourth opening 1166, a fifth opening 3165, and a sixth opening 3166.

The third opening 1165 may overlap at least a portion of the gate electrode 1151 of the driving transistor T1. The third opening 1165 may be further formed on the third gate insulating layer 143, the first interlayer insulating layer 161, and the second gate insulating layer 142. The third opening 1165 may overlap the opening 1152 of the first storage electrode 1153. The third opening 1165 may be disposed inside the opening 1152 of the first storage electrode 1153. The fourth opening 1166 may at least partially overlap the boost capacitor Cbt. The fourth opening 1166 may be further formed in the third gate insulating layer 143.

The fifth opening 3165 may overlap at least a portion of the second area 1133 of the driving transistor T1. The fifth opening 3165 may be further formed in the third gate insulating layer 143, the first interlayer insulating layer 161, the second gate insulating layer 142, and the first gate insulating layer 141. The sixth opening 3166 may overlap at least a portion of the first area 3136 of the third transistor T3. The sixth opening 3166 may be further formed in the third gate insulating layer 143.

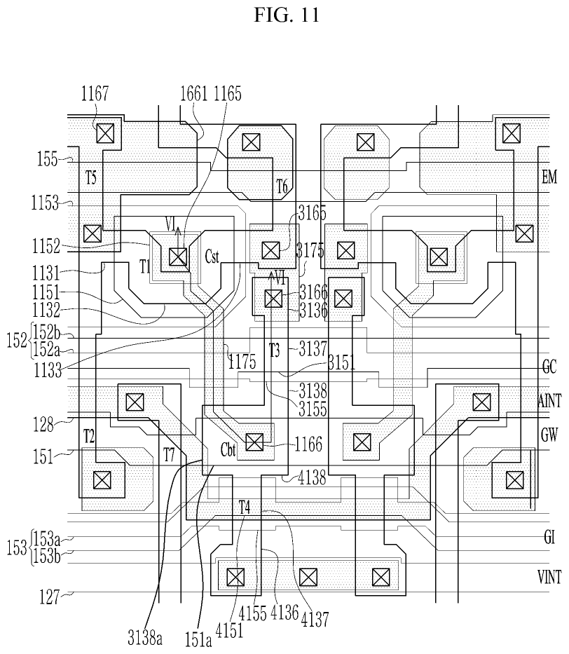

A first data conductor including a second connection electrode 1175, a third connection electrode 3175, and a fourth connection electrode 1661 may be disposed on the second interlayer insulating layer 162. FIG. 11 illustrates a polycrystalline semiconductor layer, a first gate conductor, a second gate conductor, an oxide semiconductor layer, a third gate conductor, and a first data conductor together.

The second connection electrode 1175 may overlap the gate electrode 1151 of the driving transistor T1. The second connection electrode 1175 may be connected to the gate electrode 1151 of the driving transistor T1 through the third opening 1165 and the opening 1152 of the first storage electrode 1153. The second connection electrode 1175 may overlap the boost capacitor Cbt. The second connection electrode 1175 may be connected to the upper boost electrode 3138t of the boost capacitor Cbt through the fourth opening 1166. Accordingly, the gate electrode 1151 of the driving transistor T1 and the upper boost electrode 3138t of the boost capacitor Cbt may be connected by the second connection electrode 1175. In this case, the gate electrode 1151 of the driving transistor T1 may also be connected to the second area 3138 of the third transistor T3 and the second area 4138 of the fourth transistor T4 by the second connection electrode 1175.

The third connection electrode 3175 may overlap the second area 1133 of the driving transistor T1. The third connection electrode 3175 may be connected to the second area 1133 of the driving transistor T1 through the fifth opening 3165. The third connection electrode 3175 may overlap the first area 3136 of the third transistor T3. The third connection electrode 3175 may be connected to the first area 3136 of the third transistor T3 through the sixth opening 3166. Accordingly, the second area 1133 of the driving transistor T1 and the first area 3136 of the third transistor T3 may be connected by the third connection electrode 3175.

The fourth connection electrode 1661 may overlap the first area 1135 of the fifth transistor T5, and the fourth connection electrode 1661 may be connected to the first area 1135 of the fifth transistor T5 through a contact hole 1167. Accordingly, the first area 1135 of the fifth transistor T5 and the driving voltage line 172 are connected to each other by the fourth connection electrode 1661, to transfer the driving voltage ELVDD to the first area 1135 of the fifth transistor.

The first data conductor may further include a second initialization voltage line 128. The second initialization voltage line 128 may extend substantially in the horizontal direction.

A third interlayer insulating layer 163 may be disposed on the first data conductor including the second connection electrode 1175, the third connection electrode 3175, and the fourth connection electrode 1661.

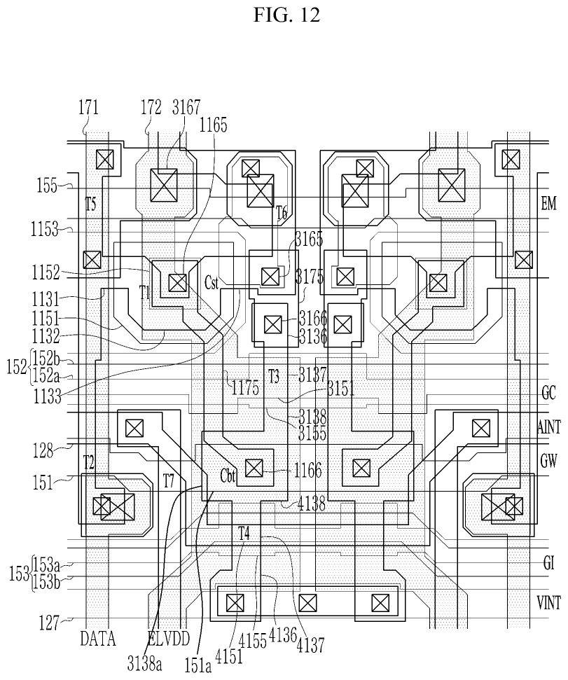

A second data conductor including the data line 171 and the driving voltage line 172 may be disposed on the third interlayer insulating layer 163. FIG. 12 illustrates a polycrystalline semiconductor layer, a first gate conductor, a second gate conductor, an oxide semiconductor layer, a third gate conductor, a first data conductor, and a second data conductor together.

The data line 171 and the driving voltage line 172 may mainly extend in the vertical direction. The data line 171 may be connected to the second transistor T2. The driving voltage line 172 may be connected to the first area 1135 of the fifth transistor T5 through a contact hole 1166, a contact hole 3167, and the fourth connection electrode 1661. In addition, the driving voltage line 172 may be connected to the first storage electrode 1153.

A passivation layer 180 may be disposed on the data line 171 and the driving voltage line 172. Although not illustrated in FIG. 3 to FIG. 5, a pixel electrode may be disposed on the passivation layer 180. A pixel definition layer (not illustrated) may be disposed on the pixel electrode, and it may include a light emitting element layer (not illustrated) disposed within a pixel opening of the pixel definition layer, and a common electrode (not illustrated) disposed over the pixel definition layer and the light emitting element layer.

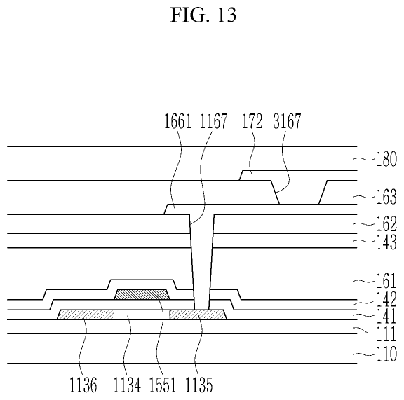

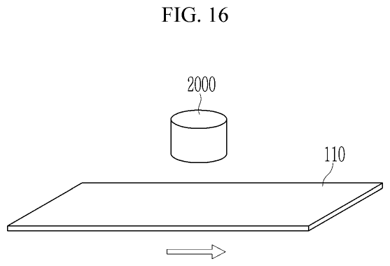

Next, a display device according to an embodiment will be described in more detail with reference to FIG. 13 to FIG. 16 together with FIG. 1 to FIG. 12. FIG. 13 to FIG. 15 each illustrate a cross-sectional view of a display device according to an embodiment, and FIG. 16 illustrates a schematic view showing a manufacturing method of a display device according to an embodiment.

As described above, the driving voltage line 172 is connected to the first area 1135 of the fifth transistor T5 through the contact hole 1166, the contact hole 3167, and the fourth connection electrode 1661, and the fifth transistor T5 is connected to the driving transistor T1. Accordingly, the first area 1131 of the driving transistor T1 is connected to the driving voltage line 172 through the fifth transistor T5 to receive the driving voltage ELVDD.

In addition, as described above, a doping process may be performed after forming the first gate conductor, and the first area 1135 and the second area 1136 disposed at opposite sides of the channel area 1134 of the fifth transistor T5 may be doped with impurities to have a same characteristic as a conductor by performing the doping process. As an amount of impurities doped in the first area 1135 and the second area 1136 of the fifth transistor T5 increases, conductivity of the first area 1135 and the second area 1136 disposed at opposite sides of the channel area 1134 of the fifth transistor T5 may be increased, and the driving voltage ELVDD applied to the driving voltage line 172 may be more easily transferred through the fifth transistor T5.

Conversely, as the amount of impurities doped in the first area 1135 and the second area 1136 disposed at opposite sides of the channel area 1134 of the fifth transistor T5 decreases, the conductivity of the first area 1135 and the second area 1136 disposed at opposite sides of the channel area 1134 of the fifth transistor T5 is relatively lower, and the driving voltage ELVDD applied to the driving voltage line 172 is difficult to be transferred through the fifth transistor T5.

As illustrated in FIG. 1, the display area DA according to an embodiment may include a first area Ra disposed close to the first driving signal transmission line 400, a second area Rb disposed far from the first driving signal transmission line 400, and a third area DA disposed between the first area Ra and the second area Rb.

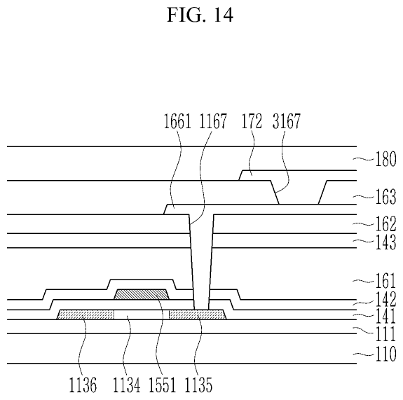

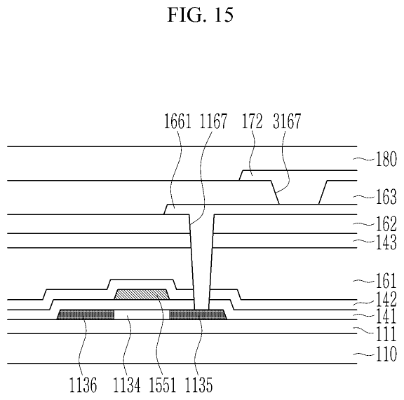

FIG. 13 illustrates a cross-sectional view of the fifth transistor T5 of one pixel PX disposed in the first area Ra of the display area DA of the display device; FIG. 14 illustrates a cross-sectional view of the fifth transistor T5 of one pixel PX disposed in the third area Rc of the display area DA; and FIG. 15 illustrates a cross-sectional view of the fifth transistor T5 of one pixel PX disposed in the second area Rb of the display area DA. As illustrated in FIG. 13 to FIG. 15, as a concentration of impurities doped in the first area 1135 and the second area 1136 disposed at opposite sides of the channel area 1134 of the fifth transistor T5 increases, the first area 1135 and the second area 1136 are darkly displayed.

Referring to FIG. 13 to FIG. 15, a concentration of the impurities doped in the first area 1135 and the second area 1136 of the fifth transistor T5 of one pixel PX disposed in the third area Rc of the display area DA is higher than that of impurities doped in the first area 1135 and the second area 1136 of the fifth transistor T5 of one pixel PX disposed in the first area Ra of the display area DA. In addition, a concentration of impurities doped in the first area 1135 and the second area 1136 of the fifth transistor T5 of one pixel PX disposed in the second area Rb of the display area DA is higher than that of impurities doped in the first area 1135 and the second area 1136 of the fifth transistor T5 of one pixel PX disposed in the third area Rc of the display area DA.

As such, it moves away from the first driving signal transmission line 400 toward the first region Ra, the third region Rc, and the second region Rb in the first direction DR1, and as a position of each pixel PX is further away from the first driving signal transmission line 400, a concentration of impurities doped in the first area 1135 and the second area 1136 of the fifth transistor T5 of each pixel PX may be increased, and thus, the driving voltage ELVDD applied to the driving voltage line 172 may be relatively better transferred through the fifth transistor T5.

When a first driving signal is transmitted to the display area DA through the first driving signal transmission line 400, a magnitude of the first driving signal may be reduced toward the first area Ra, the third area Rc, and the second area Rb by resistance of a driving signal line of the display area DA connected to the first driving signal transmission line 400. However, in accordance with the display device according to the embodiment, the concentration of impurities doped in the first area 1135 and the second area 1136 of the fifth transistor T5 of the pixel PX disposed in the third area Rc is higher than that of impurities doped in the first area 1135 and the second area 1136 of the fifth transistor T5 of the pixel PX disposed in the first area Ra, and the concentration of impurities doped in the first area 1135 and the second area 1136 of the fifth transistor T5 of the pixel PX disposed in the second area Rb is higher than that of impurities doped in the first area 1135 and the second area 1136 of the fifth transistor T5 of the pixel PX disposed in the third area Rc, and thus a magnitude of the driving signal transferred to the display area DA may be substantially constantly maintained regardless of which area each pixel PX is disposed in among the first area Ra, the third area Rc, and the second area Rb by compensating for a decrease in the magnitude of the driving signal toward the first area Ra, the third area Rc, and the second area Rb by the resistance of the driving signal line.

According to an embodiment illustrated in FIG. 13 to FIG. 15, although it has been described that the concentration of impurities doped in the first region 1135 and the second region 1136 of the fifth transistor T5 is varied depending on which area each pixel PX is disposed in among the first area Ra, the third area Rc, and the second area Rb, but the embodiments are not limited thereto, and the concentration of impurities doped in the first area 1131 and the second area 1133 of the driving transistor T1, or a first area and a second area disposed at opposite sides of the channel area of the sixth transistor T6, disposed between the driving voltage line 172 and the light emitting diode LED may be varied. That is, the concentration of impurities doped in the first area 1131 and the second area 1133 of the driving transistor T1 or the first area and the second area of the sixth transistor T6 of the pixel PX disposed in the third area Rc may be higher than that of impurities doped in the first area 1131 and the second region 1133 of the driving transistor T1 of the pixel PX disposed in the first region Ra or the first area and the second area of the sixth transistor T6, and the concentration of impurities doped in the first area 1131 and the second area 1133 of the driving transistor T1 or the first area and the second area of the sixth transistor T6 of the pixel PX disposed in the second region Rb may be higher than that of impurities doped in the first area 1131 and the second area 1133 of the driving transistor T1 or the first area and the second area of the sixth transistor T6 of the pixel PX disposed in the second area Rb may be higher than that of impurities doped in the first area 1131 and the second area 1133 or the first area and the second area of the sixth transistor T6 of the driving transistor T1 of the pixel PX disposed in the third area Rc. Accordingly, a magnitude of the driving signal transferred to the display area DA may be substantially constantly maintained regardless of which area each pixel PX is disposed in among the first area Ra, the third area Rc, and the second area Rb by compensating for a decrease in the magnitude of the driving signal toward the first area Ra, the third area Rc, and the second area Rb by the resistance of the driving signal line.

Now, a method of differently controlling the concentration of impurities doped in the first area 1135 and the second area 1136 of the fifth transistor T5 will be described depending on the position of the display area DA of the display device with reference to FIG. 16.

Referring to FIG. 16, when a doping process is performed after forming the buffer layer 111, a polycrystalline semiconductor layer, a first gate insulating layer 141, and a first gate conductor on the substrate 110, it is possible to dope impurities by discharging the impurities from an impurity doping device 2000 while moving the substrate 110 in a direction of an arrow.

When the first area Ra of the display area DA is doped with impurities, the substrate 110 is moved at a first speed; when the third region Rc is doped with impurities, the substrate 110 is moved at a second speed; and when the second region Rb is doped with impurities, the substrate 110 may be moved at a third speed. The first speed may be faster than the second speed, and the second speed may be faster than the third speed.

The substrate 110 moves more slowly when the third area Rc is doped with impurities than when the first area Ra is doped with impurities, so that the concentration of impurities doped in the first area 1135 and the second area 1136 of the fifth transistor T5 disposed in the third area Rc may be higher than that of impurities doped in the first area 1135 and the second area 1136 of the fifth transistor T5 disposed in the first area Ra. Similarly, the substrate 110 moves more slowly when the second area Rb is doped with impurities than when the third area Rc is doped with impurities, so that the concentration of impurities doped in the first area 1135 and the second area 1136 of the fifth transistor T5 disposed in the second area Rb may be higher than that of impurities doped in the first area 1135 and the second area 1136 of the fifth transistor T5 disposed in the third area Rc.

As such, the concentration of impurities doped in the first area 1135 and the second area 1136 of the fifth transistor T5 may be controlled depending on the position of the display area DA in a simple way by adjusting a moving speed of the substrate 110 when it is doped with the impurities.

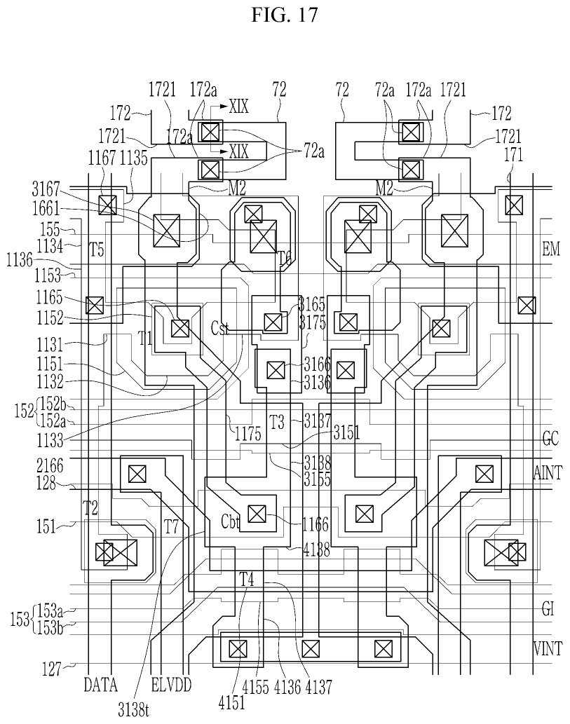

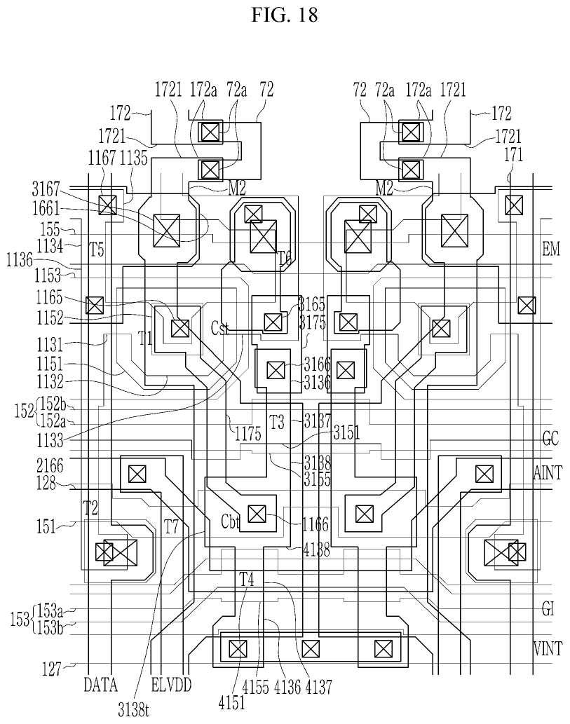

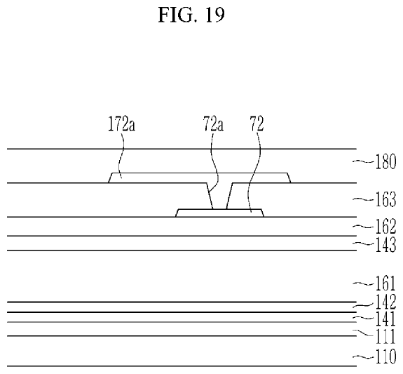

Next, a display device according to another embodiment will be described with reference to FIG. 17 and FIG. 18 and FIG. 19 to FIG. 21 together with FIG. 1 to FIG. 12. FIG. 17 and FIG. 18 each illustrate a top plan view of one pixel of a display device according to another embodiment, and FIG. 19 to FIG. 21 each illustrate a cross-sectional view of a portion of one pixel of a display device according to another embodiment.

As illustrated in FIG. 1, the display area DA according to an embodiment may include a first area Ra disposed close to the first driving signal transmission line 400, a second area Rb disposed far from the first driving signal transmission line 400, and a third area DA disposed between the first area Ra and the second area Rb.

FIG. 3 illustrates a top plan view of one pixel PX disposed in the second area Rb of the display area DA; FIG. 17 illustrates a top plan view of one pixel PX disposed in the first area Ra of the display area DA; and FIG. 18 illustrates a top plan view of one pixel PX disposed in the third area Rc of the display area DA.

Referring to FIG. 3 and FIG. 17 and FIG. 18, unlike the pixel PX disposed in the second area Rb of the display area DA, in the pixel PX disposed in the third area Rc of the display area DA and the pixel PX disposed in the first area Ra of the display area DA, the driving voltage line 172 is cut to have opposite ends 1721, the pixel PX disposed in the third area Rc and the pixel PX disposed in the first area Ra of the display area DA further have a resistance pattern 72 connected to the opposite ends 1721 of the driving voltage line 172 through a contact hole 72a, and the opposite ends 1721 of the driving voltage line 172 may be connected to each other through a resistance pattern 72 to transfer the driving voltage applied to the driving voltage line 172 through the resistance pattern 72. Accordingly, compared to the pixel PX without the resistance pattern 72, the driving voltage ELVDD transferred to the pixel PX on which the resistance pattern 72 is disposed may be smaller.

In addition, a magnitude of resistance applied to a voltage passing through the resistance pattern 72 may be changed depending on a width and a length of the resistance pattern 72. For example, when the width of the resistance pattern 72 is constant and the length of the resistance pattern 72 is changed, the magnitude of the resistance may be increased as the length of the resistance pattern 72 is increased, and when the length is constant and the width is changed, the magnitude of the resistance may be decreased as the width of the resistance pattern 72 is increased.

Referring to FIG. 17 and FIG. 18, widths of the resistance pattern 72 of one pixel PX disposed in the first area Ra of the display area DA and the resistance pattern 72 of one pixel PX disposed in the third area Rc of the display area DA may be the same, and the length of the resistance pattern 72 of one pixel PX disposed in the first area Ra may be longer than that of the resistance pattern 72 of one pixel PX disposed in the third area Rc.

Accordingly, in the case of the pixels PX disposed in the first area Ra and the third area Rc of the display area DA, the driving voltage ELVDD applied to the driving voltage line 172 is transferred via the fifth transistor T5 and the resistance pattern 72, and thus the magnitude of the transmitted driving voltage ELVDD may be smaller compared to the pixel PX disposed in the second area Rb to which the driving voltage ELVDD is directly transferred because there is no resistance pattern 72, and the magnitude of the driving voltage ELVDD transferred to the pixel PX disposed in the first area Ra may be smaller than that of the driving voltage ELVDD transferred to the pixel PX disposed in the third area Rc.

As such, the magnitude of the resistance caused by the resistance pattern 72 which moves away from the first driving signal transmission line 400 toward the first region Ra, the third region Rc, and the second region Rb along the first direction DR1 and is connected to the extension 172a of the opposite ends 1721 of the driving voltage line 172 in the first area Ra closest to the first driving signal transmission line 400 may be relatively large, and the magnitude of the resistance caused by the resistance pattern 72 which is connected to the extension 172a of the opposite end portions 1721 of the driving voltage line 172 in the third area Rc farther from the first driving signal transmission line 400 than the first area Ra may be relatively smaller.

Accordingly, a magnitude of the driving signal transferred to the display area DA may be substantially constantly maintained regardless of which area each pixel PX is disposed in among the first area Ra, the third area Rc, and the second area Rb by compensating for a decrease in the magnitude of the driving signal toward the first area Ra, the third area Rc, and the second area Rb by the resistance of the driving signal line.

Now, an interlayer structure of the resistance pattern 72 of the pixels PX disposed in the first area Ra and the third area Rc will be described with reference to FIG. 19 to FIG. 21.

Referring to FIG. 19, the resistance pattern 72 disposed in the first area Ra and the third area Rc of the display area DA may be formed in a same layer including the second connection electrode 1175, the third connection electrode 3175, and the fourth connection electrode 1661, and may be disposed on the second interlayer insulating layer 162. The driving voltage line 172 may be connected to the resistance pattern 72 through the contact hole 72a of the third interlayer insulating layer 163, and the driving voltage ELVDD applied to the driving voltage line 172 may be transferred via the resistance pattern 72.

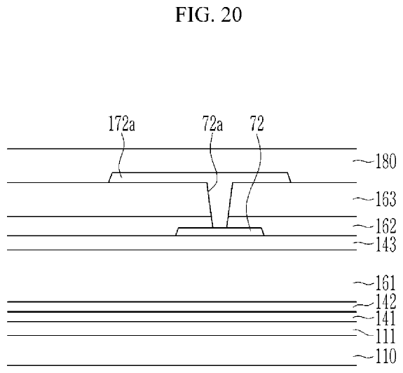

Referring to FIG. 20, the resistance pattern 72 disposed in the first area Ra and the third area Rc of the display area DA may be formed in a same layer as a third gate conductor including the upper gate electrode 3151 of the third transistor T3 and the upper gate electrode 4151 of the fourth transistor T4, and may be disposed on the third gate insulating layer 143. The driving voltage line 172 may be connected to the resistance pattern 72 through the contact hole 72a of the third interlayer insulating layer 163 and the second interlayer insulating layer 162, and the driving voltage ELVDD applied to the driving voltage line 172 may be transferred via the resistance pattern 72.

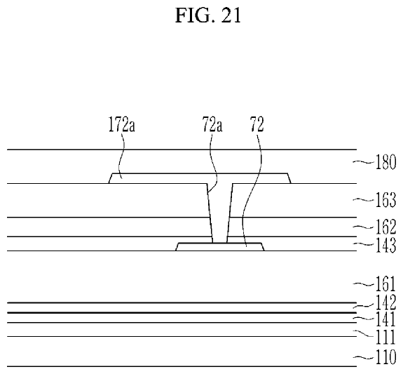

Referring to FIG. 21, the resistance pattern 72 disposed in the first area Ra and the third area Rc of the display area DA may be formed in a same layer as an oxide semiconductor layer including the channel 3137, the first area 3136, and the second area 3138 of the third transistor T3, and the channel 4137, the first area 4136, and the second area 4138 of the fourth transistor T4, and may be disposed on the first interlayer insulating layer 161. The driving voltage line 172 may be connected to the resistance pattern 72 through the contact hole 72a of the third interlayer insulating layer 163, the second interlayer insulating layer 162, and the third gate insulating layer 143, and the driving voltage ELVDD applied to the driving voltage line 172 may be transferred via the resistance pattern 72.

According to the embodiment described with reference to FIG. 3, FIG. 17, and FIG. 18, and FIG. 19 to FIG. 21, the resistance pattern 72 of the pixel PX disposed in the first area Ra and the third area Rc has been described as being connected to the opposite ends 1721 of the driving voltage line 172 disposed between the driving voltage line 172 and the fifth transistor T5, but the embodiments are not limited thereto, and the resistance pattern 72 may be disposed between the fifth transistor T5 and the first transistor T1, between the first transistor T1 and the sixth transistor T6, and between the sixth transistor T6 and the common voltage line 741.

In addition, according to the embodiment described with reference to FIG. 3, FIG. 17, and FIG. 18, and FIG. 19 to FIG. 21, although it has been described that the pixel PX disposed in the first area Ra and the third area Rc includes the resistance pattern 72, and the pixel PX disposed in the second region Rb does not include the resistance pattern 72, the inventive concepts are not limited thereto, and the pixel PX disposed in the second area Rb also includes the resistance pattern 72, and in this case, the magnitude of the resistance by the resistance pattern 72 of the pixel PX disposed in the second area Rb may be smaller than the resistance of the resistance pattern 72 of the pixel PX disposed in the third area Rc.

According to the embodiment described with reference to FIG. 3, FIG. 17, and FIG. 18, and FIG. 19 to FIG. 21, although it has been described that the width of the resistance pattern 72 of the pixel PX disposed in the first area Ra and the third area Rc is constant and the length thereof varies, the inventive concepts are not limited thereto, and many features that can change the magnitude of the resistance by the resistance pattern 72 are all applicable.

As such, in accordance with the display device according to the embodiment, concentrations of impurities doped in the first area 1135 and the second area 1136 of the fifth transistor T5 connected to the driving voltage line 172 of each pixel PX disposed in the first area Ra disposed close to the first driving signal transmission line 400, the second area Rb disposed far from the first driving signal transmission line 400, and the third area Rc disposed between the first area Ra and the second area Rb may be differently set or the magnitude of the resistance by the resistance pattern 72 connected to the driving voltage line 172 of each pixel PX may be differently set, thereby substantially constantly maintaining the magnitude of the driving signal transferred to the display area DA regardless of which area each pixel PX is disposed in among the first area Ra, the third area Rc, and the second area Rb.

Although certain embodiments and implementations have been described herein, other embodiments and modifications will be apparent from this description. Accordingly, the inventive concepts are not limited to such embodiments, but rather to the broader scope of the appended claims and various obvious modifications and equivalent arrangements as would be apparent to a person of ordinary skill in the art.

### DESCRIPTION OF SYMBOLS

1000: display device

110: substrate

111: buffer layer

141, 142, 143: gate insulating layer

151, 152: scan line

153: initialization control line

154: bypass control line

155: emission control line

161, 162, 163: interlayer insulating layer

171: data line

172: driving voltage line

172a: extension

72: resistance pattern

400, 500: driving signal transmission line

1132, 1134: channel

1131, 1135: first area

1133, 1136: second area

1151, 1551: gate electrode

1661: connection electrode

Ra: first area

Rb: second area

Rc: third area

What is claimed is:

1. A display device comprising:
a display area including a plurality of pixels; and
a peripheral area disposed around the display area and including a driving signal transmission line,
wherein:
each of the pixels includes a transistor, a driving voltage line connected to the transistor and the driving signal transmission line, and a light emitting unit connected to the transistor;
the pixels include a first pixel and a second pixel spaced apart from the driving signal transmission line to have different distances from each other; and
a concentration of impurities doped in a semiconductor layer of the transistor of the first pixel is different from a concentration of impurities doped in a semiconductor layer of the transistor of the second pixel.

2. The display device of claim 1, wherein:
a distance between the driving signal transmission line and the second pixel is greater than a distance between the driving signal transmission line and the first pixel; and
the concentration of the impurities doped in the semiconductor layer of the transistor of the second pixel is greater than the concentration of the impurities doped in the semiconductor layer of the transistor of the first pixel.

3. The display device of claim 2, wherein:
the semiconductor layer of the transistor includes a channel overlapping a gate electrode, and first and second regions disposed on opposite sides of the channel;
the first region of the transistor is connected to the driving voltage line; and
the transistor receives a driving voltage from the driving voltage line.

4. The display device of claim 3, wherein the first region and the second region of the transistor are doped with the impurities.

5. The display device of claim 4, further comprising a resistance pattern connected to the driving voltage line of the first pixel.

6. The display device of claim 1, wherein:
the display area includes a first area disposed close to the driving signal transmission line, a second area disposed farther from the driving signal transmission line than the first region, and a third area disposed between the first area and the second area;
the first pixel is disposed in the first area, the second pixel is disposed in the second area; and
the concentration of the impurities doped in the semiconductor layer of the transistor of the second pixel is greater than the concentration of the impurities doped in the semiconductor layer of the transistor of the first pixel.

7. The display device of claim 6, wherein:
the pixels further include a third pixel disposed in the third area; and
a concentration of impurities doped in the semiconductor layer of the transistor of the third pixel is greater than the concentration of the impurities doped in the semiconductor layer of the transistor of the first pixel, and is less than the concentration of the impurities doped in the semiconductor layer of the transistor of the second pixel.

8. The display device of claim 7, wherein:
the semiconductor layer of the transistor includes a channel overlapping a gate electrode, and first and second regions disposed on opposite sides of the channel;
the first region of the transistor is connected to the driving voltage line; and
the transistor receives a driving voltage from the driving voltage line.

9. The display device of claim 8, wherein the first region and the second region of the transistor are doped with the impurities.

10. The display device of claim 9, wherein:
a first resistor is connected to the driving voltage line of the first pixel and a second resistor is connected to the driving voltage line of the third pixel; and
a resistance of the first resistor is different from a resistance of the second resistor.

11. The display device of claim 10, wherein the resistance of the first resistor is greater than the resistance of the second resistor.

12. A display device comprising:
a display area configured to include a plurality of pixels; and
a peripheral area disposed around the display area to include a driving signal transmission line,
wherein:
the pixels include a first pixel and a second pixel spaced apart from the driving signal transmission line to have different distances from each other;
a distance between the driving signal transmission line and the second pixel is greater than a distance between the driving signal transmission line and the first pixel;
the first pixel includes a transistor, a driving voltage line connected to the transistor and the driving signal transmission line, and a first resistor connected to the driving voltage line; and
the second pixel includes the transistor and the driving voltage line.

13. The display device of claim 12, wherein the driving voltage line of the second pixel is not connected to the first resistor.

14. The display device of claim 13, wherein:
the display area includes a first area disposed close to the driving signal transmission line, a second area disposed farther from the driving signal transmission line than the first region, and a third area disposed between the first area and the second area;
the first pixel is disposed in the first area, the second pixel is disposed in the second area;
the driving voltage line of the third pixel disposed in the third area is connected to a second resistor; and
a resistance of the first resistor is different from a resistance of the second resistor.

15. The display device of claim 14, wherein the resistance of the first resistor is greater than the resistance of the second resistor.

16. The display device of claim 12, wherein:
the display area includes a first area disposed close to the driving signal transmission line, a second area disposed farther from the driving signal transmission line than the first region, and a third area disposed between the first area and the second area;
the first pixel is disposed in the first area, the second pixel is disposed in the second area;
the driving voltage line of the third pixel disposed in the third area is connected to a second resistor; and
a resistance of the first resistor is different from a resistance of the second resistor.

17. The display device of claim 16, wherein:
the resistance of the first resistor is greater than the resistance of the second resistor.

18. The display device of claim 12, wherein:
the first resistor includes a first resistance pattern;
the first resistance pattern is disposed under the driving voltage line with an insulating layer therebetween; and
the driving voltage line is connected to the first resistance pattern through a contact hole of the insulating layer.

19. The display device of claim 18, wherein:
the pixels include a semiconductor layer, a gate conductor overlapping the semiconductor layer, and a data conductor connected to the semiconductor layer; and
the first resistance pattern is formed at a same layer as any one of the semiconductor layer, the gate conductor, and the data conductor.

20. The display device of claim 19, wherein a concentration of impurities doped in a semiconductor layer of the transistor of the first pixel is different from a concentration of impurities doped in a semiconductor layer of the transistor of the second pixel.
